(19) United States
(12) Patent Application Publication
(10) Pub. No.: US 2018/0130794 A1
(43) Pub. Date: May 10, 2018

(54) ELECTRONIC CIRCUIT, INTEGRATED CIRCUIT AND MOTOR ASSEMBLY

(71) Applicant: Johnson Electric S.A., Murten (CH)

(72) Inventors: Chiping SUN, Hong Kong (CN); Ken WONG, Hong Kong (CN); Shujuan HUANG, Shenzhen (CN); Yunlong JIANG, Shenzhen (CN); Shinghin YEUNG, Hong Kong (CN)

(21) Appl. No.: 15/802,985

(22) Filed: Nov. 3, 2017

(30) Foreign Application Priority Data
Nov. 4, 2016 (CN) 2016 1096 6318.4

(51) Int. Cl. H01L 27/02; H01L 27/04; H02H 9/04

(52) U.S. Cl. CPC H01L 27/0292; H01L 27/04; H02H 9/042; H02H 9/046; H02H 9/043

(57) ABSTRACT

An electronic circuit includes an output port, a first AC input port and a second AC input port connecting with an external AC power source, a rectifier circuit and an electrostatic protection circuit. The rectifier circuit includes a first input terminal coupling with the first AC input port, a second input terminal coupling with the second AC input port, a first output terminal and a second output terminal. A voltage of the first output terminal is larger than a voltage of the second output terminal. The electrostatic protection circuit includes a first unidirectional electrostatic protection circuit coupled between the first output terminal of the rectifier circuit and the second output terminal of the rectifier circuit.

### CROSS REFERENCE TO RELATED APPLICATIONS

This non-provisional patent application claims priority under 35 U.S.C. § 119(a) from Patent Application No. 201610966318.4 filed in the People's Republic of China on Nov. 4, 2016.

### TECHNICAL FIELD

The present disclosure relates to electrostatic protection field, in particular to an electrostatic protecting circuit, an integrated circuit and a motor assembly using the integrated circuit.

### BACKGROUND

ESD (Electro-Static Discharge) can damage electronic components or make an electrical over stress (ESO) of an integrated circuit. Moreover, due to a very high ESD voltage, the electronic components or integrated circuit can be damaged permanently; the electronic components and integrated circuit can't normally work. Therefore, the prevention of electrostatic damage has become an important research direction for the design and manufacture of electronic components and integrated circuit.

For an integrated circuit, an electrostatic protection circuit can be arranged in a DC input port and a DC output port. However, the electrostatic protection circuit can't be used in an integrated circuit which is powered by an AC power source.

### SUMMARY

An electronic circuit includes an output port, a first AC input port and a second AC input port connecting with an external AC power source, a rectifier circuit and an electrostatic protection circuit. The rectifier circuit includes a first input terminal coupling with the first AC input port, a second input terminal coupling with the second AC input port, a first output terminal and a second output terminal. A voltage of the first output terminal is larger than a voltage of the second output terminal. The electrostatic protection circuit includes a first unidirectional electrostatic protection circuit coupled between the first output terminal of the rectifier circuit and the second output terminal of the rectifier circuit.

Preferably, the second output terminal is a floating ground end.

Preferably, an input terminal of the first unidirectional electrostatic circuit is electrically coupled with the first output terminal of the rectifier circuit; and an output terminal of the first unidirectional electrostatic circuit is electrically coupled with the second output terminal of the rectifier circuit.

Preferably, the electronic circuit can further include comprising a Zener diode and a current limiting resistor coupled between the first output terminal of the rectifier circuit and the second output terminal of the rectifier circuit in series.

Preferably, the electrostatic protection circuit comprises a second unidirectional electrostatic protection circuit coupled between the first AC input port and the second AC input port, a third unidirectional electrostatic protection circuit coupled between the first input terminal of the rectifier circuit and the second output terminal of the rectifier circuit, and/or a fourth unidirectional electrostatic protection circuit coupled between the second input terminal of the rectifier circuit and the second output terminal of the rectifier circuit.

Preferably, at least one of the first, second, third, and fourth unidirectional electrostatic protection circuit comprises at least one semiconductor element; when an static electricity is not generated in the electronic circuit, the at least one semiconductor element is in a high resistance state, and when the static electricity is generated in the electronic circuit, the at least one semiconductor element operates in an avalanche breakdown state to form a discharge path to release the static electricity.

Preferably, at least one of the first, second, third, and fourth unidirectional electrostatic protection circuit comprises an electrostatic detection circuit and a semiconductor element, and when an static electricity is not generated in the electronic circuit, the semiconductor element is in a high resistance state; and when the static electricity is generated in the electronic circuit, the semiconductor element is controlled to be conductive by the electrostatic detection circuit to form a discharge path to release the static electricity.

Preferably, at least one of the first, second, third, and fourth unidirectional electrostatic protection circuit comprises a Zener diode, an anode of the Zener diode is electrically coupled between an input terminal and an output terminal of the unidirectional electrostatic protection circuit.

Preferably, at least one of the first, second, third, and fourth unidirectional electrostatic protection circuit comprises a first NMOS transistor, a drain of the first NMOS transistor is electrically coupled to an input terminal of the unidirectional electrostatic protection circuit and a gate, and a source of the first NMOS transistor is electrically coupled to an output terminal of the unidirectional electrostatic protection circuit.

Preferably, at least one of the first, second, third, and fourth unidirectional electrostatic protection circuit comprises a silicon controlled rectifier; an anode of the silicon controlled rectifier is electrically coupled to an input terminal of the unidirectional electrostatic protection circuit, a cathode of the silicon controlled rectifier is electrically coupled to an output terminal of the unidirectional electrostatic protection circuit, and a control terminal receives an external control signal.

Preferably, at least one of the first, second, third, and fourth unidirectional electrostatic protection circuit comprises a PNP transistor and an NPN transistor; and a base electrode of the PNP transistor is electrically coupled with a collector electrode of the NPN transistor, a collector electrode of the PNP transistor is electrically coupled with a base electrode of the NPN transistor, an emitter electrode of the PNP transistor is electrically coupled with an input terminal of the unidirectional electrostatic protection circuit, and an emitter electrode of the NPN transistor is electrically coupled with an output terminal of the unidirectional electrostatic protection circuit.

Preferably, a plurality of diodes is coupled between the collector electrode and the emitter electrode of the NPN transistor.

Preferably, at least one of the first, second, third, and fourth unidirectional electrostatic protection circuit comprises a first resistor, a first capacitor, a first PMOS transistor, a second NMOS transistor, a second resistor, and a third NMOS transistor; one end of the first resistor is electrically coupled with an input terminal of the unidirectional electrostatic protection circuit, the other end of the first resistor is electrically coupled with one end of the first capacitor; the other end of the first capacitor coupled with an output terminal of the unidirectional electrostatic protection circuit; a drain of the first PMOS transistor is coupled with an input terminal of the unidirectional electrostatic protection circuit, a gate of the first PMOS transistor is coupled with the other end of the first resistor and a gate of the second NMOS transistor, a source of the first PMOS transistor is coupled to a drain of the second NMOS transistor and a gate of the third NMOS transistor, a source of the second NMOS is coupled with an output terminal of the unidirectional electrostatic protection circuit; a drain of the third NMOS transistor is coupled to the input terminal of the unidirectional electrostatic protection circuit via the second resistor, and a source of the third NMOS transistor is coupled to the output terminal of the unidirectional electrostatic protection circuit.

Preferably, at least one of the first, second, third, and fourth unidirectional electrostatic protection circuit comprises an electrostatic detection circuit, a third resistor, and a fourth NMOS transistor; a first end of the electrostatic detection circuit is coupled to an input terminal of the unidirectional electrostatic protection circuit, a second end of the electrostatic detection circuit is coupled to an output terminal of the unidirectional electrostatic protection circuit, and a third end of the electrostatic detection circuit is coupled to a gate of the fourth NMOS transistor; a source of the fourth NMOS transistor is coupled with the output terminal of the unidirectional electrostatic detection circuit, and a drain of the fourth NMOS transistor is coupled with the input terminal of the unidirectional electrostatic detection circuit via the third resistor.

Preferably, at least one of the first, second, third, and fourth unidirectional electrostatic protection circuit comprises a fourth resistor, a second PMOS, and a fifth NMOS transistor; a gate and a drain of the second PMOS transistor are coupled with an input terminal of the unidirectional electrostatic detection circuit, a source of the second PMOS transistor is coupled to an output terminal of the unidirectional electrostatic detection circuit via the fourth resistor; a drain of the fifth NMOS transistor is coupled with the input terminal of the unidirectional electrostatic detection circuit, a gate and a source of the fifth NMOS transistor are coupled with the output terminal of the unidirectional electrostatic detection circuit, and a substrate of the fifth NMOS transistor is coupled with the source of the second PMOS transistor.

An integrated circuit can include a housing; a substrate arranged in the housing; an electronic circuit arranged on the substrate; an output port; and a first AC input port and a second AC input port connecting with an external AC power source; and wherein the electronic circuit comprises a rectifier circuit coupled between the first AC input port and the second AC input port and a first unidirectional electrostatic protection circuit, and the first unidirectional electrostatic protection circuit is coupled between a first output terminal of the rectifier circuit and a second output terminal of the rectifier circuit.

Preferably, an input terminal of the first unidirectional electrostatic circuit is electrically coupled with the first output terminal of the rectifier circuit; and an output terminal of the first unidirectional electrostatic circuit is electrically coupled with the second output terminal of the rectifier circuit.

Preferably, a second unidirectional electrostatic protection circuit is coupled between the first AC input port and the second AC input port, a third unidirectional electrostatic protection circuit is coupled between the first input terminal of the rectifier circuit and the second output terminal of the rectifier circuit, and/or a fourth unidirectional electrostatic protection circuit is coupled between the second input terminal of the rectifier circuit and the second output terminal of the rectifier circuit.

Preferably, at least one of the first, second, third, and fourth unidirectional electrostatic protection circuit comprises at least one semiconductor element; when an static electricity is not generated in the electronic circuit, the at least one semiconductor element is in a high resistance state, and when the static electricity is generated in the electronic circuit, the at least one semiconductor element operates in an avalanche breakdown state to form a discharge path to release the static electricity.

A motor assembly can include a motor and a motor-driven circuit. And the motor-driven circuit comprises the integrated circuit described-above.

### BRIEF DESCRIPTION OF THE DRAWINGS

FIG. 1 shows a block diagram of an electronic circuit having an electrostatic protection circuit according to one embodiment.

FIGS. 2a-2d show a schematic view of a discharge path of the electrostatic protection circuit of the electronic circuit of FIG. 1.

FIG. 3 shows a block diagram of an electronic circuit having an electrostatic protection circuit according to another embodiment.

FIG. 4 shows a block diagram of an electronic circuit having an electrostatic protection circuit according to another embodiment.

FIGS. 5a-5h and 6a-6c show a circuit diagram of an electrostatic protection circuit of an electronic circuit.

FIG. 7 shows a block diagram of an integrated circuit according to one embodiment.

FIG. 8 shows a block diagram of an integrated circuit according to another embodiment.

FIG. 9 shows a block diagram of an integrated circuit according to another embodiment.

FIG. 10 shows a schematic diagram of a motor assembly according to one embodiment.

The following implementations are used for the description of the present disclosure in conjunction with above FIG.s.

### DETAILED DESCRIPTION OF THE EMBODIMENTS

Hereinafter technical solutions in embodiments of the present disclosure are described clearly and completely in conjunction with the drawings in embodiments of the present disclosure. Apparently, the described embodiments are only some rather than all of the embodiments of the present disclosure. Any other embodiments obtained based on the embodiments of the present disclosure by those skilled in the art without any creative work fall within the scope of protection of the present disclosure. It is understood that, the drawings are only intended to provide reference and illustration, and not to limit the present disclosure. The connections in the drawings are only intended for the clearance of description, and not to limit the type of connections.

It should be noted that, if a component is described to be “connected” to another component, it may be connected to another component directly, or there may be an intervening component simultaneously. All the technical and scientific terms in the present disclosure have the same definitions as the general understanding of those skilled in the art, unless otherwise defined. Herein the terms in the present disclosure are only intended to describe embodiments, and not to limit the present disclosure.

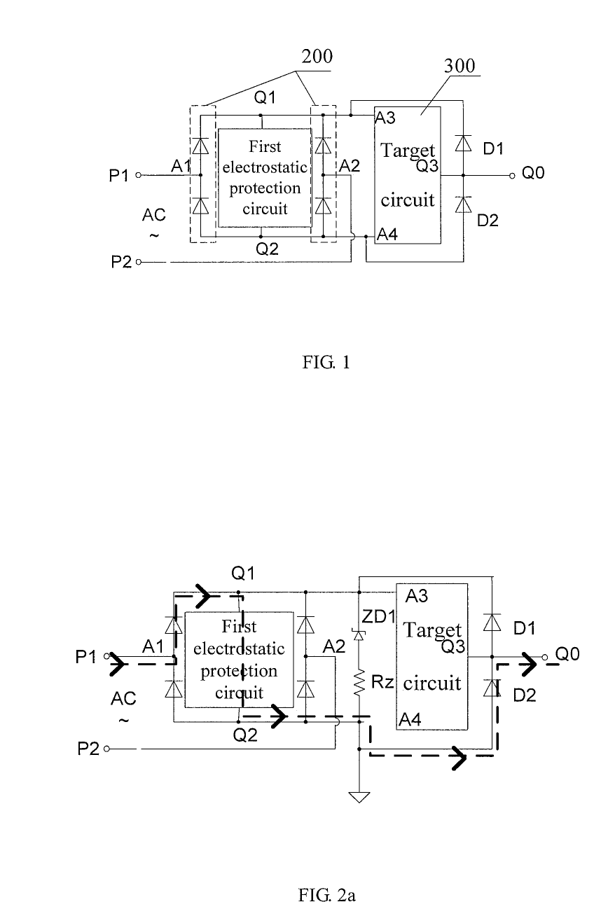

FIG. 1 shows an electronic circuit having an electrostatic function according to one embodiment. The electronic circuit can include an output port Q0, a first AC input port P1 for connecting an external AC power source AC, a second AC input port P2, an electrostatic protection circuit 100, a rectifier circuit 200, a target circuit 300, a first diode D1, and a second diode D2. A first input terminal A1 of the rectifier circuit 200 is connected to the first AC input port P1, a second input terminal A2 of the rectifier circuit 200 is connected to the second AC input port P2. A first output terminal Q1 of the rectifier circuit 200 is connected to a first input terminal A3 of the target circuit 300 and a second output terminal Q2 of the rectifier circuit 200 is connected to a second input terminal A4 of the target circuit 300.

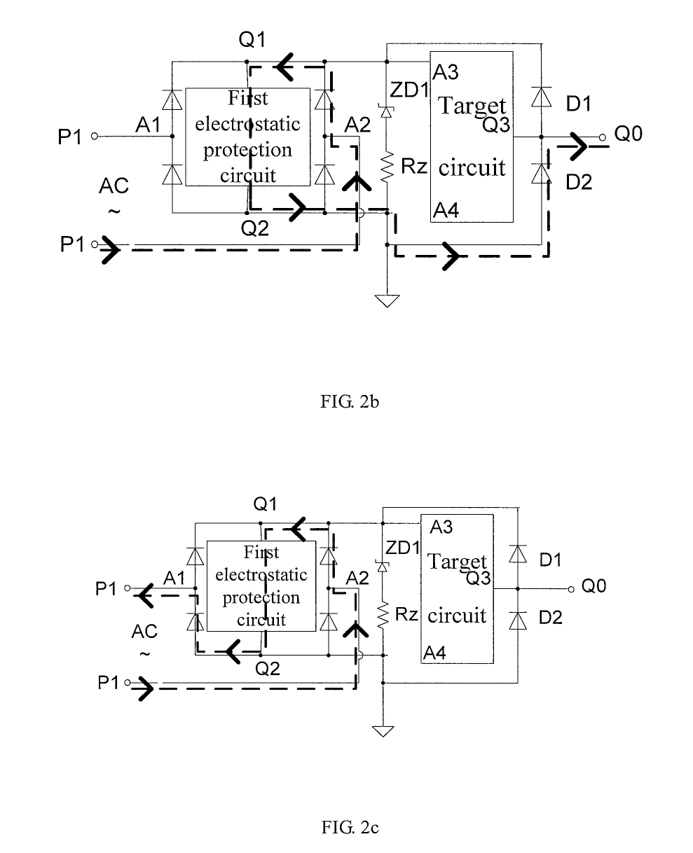

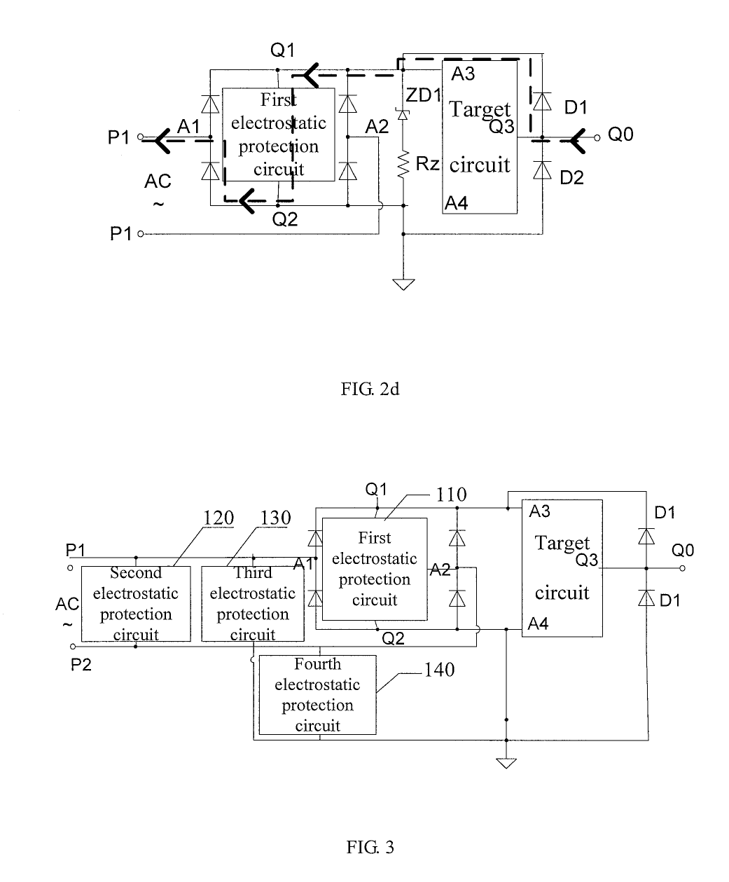

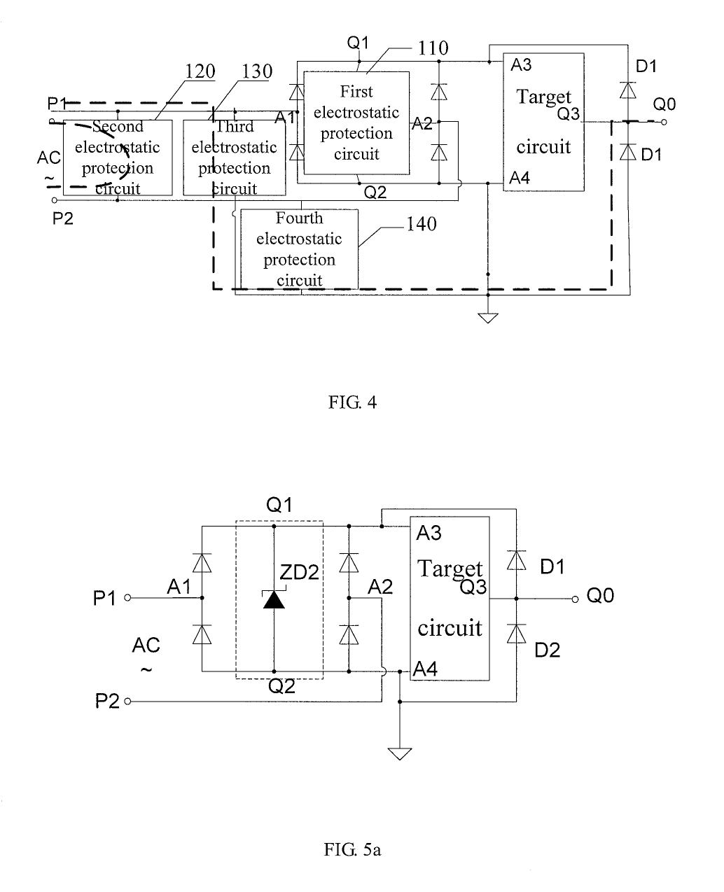

It is to be noted that, for the electronic circuit of the present application, a voltage of the first output terminal Q1 of the rectifier circuit 200 is greater than a voltage of its second output terminal Q2, and specifically, the second output terminal Q2 of the rectifier circuit 200 may be floating, as shown in FIGS. 2a-2e, but is not limited thereto.

An output terminal Q3 of the target circuit 300 is connected to the output port Q0, an anode of the first diode D1 and a cathode of the second diode D2, respectively. A cathode of the first diode D1 is connected to the first output terminal Q1 of the rectifier circuit 200, and an anode of the second diode D2 is connected to the second output terminal Q2 of the rectifier circuit 200.

The electrostatic protection circuit 100 can include a first electrostatic protection circuit 110 coupled between the first output terminal Q1 and the second output terminal Q2 of the rectifier circuit 200. In the embodiment, when the external AC power source is introduced into static electricity, a discharge path is formed between the first AC input port P1 and the second AC input port P2 of the external alternating current via the diodes in the rectifier circuit 200 and the first electrostatic protection circuit 110. The discharge path also can be formed by the diodes in the rectifier circuit 200, the first electrostatic protection circuit 110 and the output port Q0 as the dotted line shown in FIGS. 2a-2e. And thereby the static electricity introduced by the external AC power source directly released by the discharge path to avoid damaging the electronic components in the electronic circuit, particularly the target circuit. A reliability of the electronic circuit can be improved.

If the static electricity is introduced from the output port of the electronic circuit, the discharge path may be formed through the output ports Q0, the first electrostatic protection circuit 110, and the diodes in the rectifier circuit 200, as the dotted line shown in FIG. 2d, so as to avoid damaging to the electronic components of the target circuit. The present disclosure is not limited to the manner in which the electrostatic introduction in the electronic circuit is applied, but it is to be noted that, regardless of the manner in which it is possible, the discharge path may be formed by the first electrostatic protection circuit 110 and other components in the electronic circuit. A damage of the components of the target circuit by static electricity can be avoided, the present disclosure is not to be exhausted herein, and reference is made to the following description of the following embodiments.

The first electrostatic protection circuit 110 may be a unidirectional electrostatic protection circuit that forms a unidirectional discharge path by the first diode and the second diode to release the static electricity introduced into the electronic circuit. The specific circuit configuration of the first electrostatic protection circuit of the present disclosure is not limited.

The rectifier circuit 200 in each of the above embodiments may include a full-wave rectifier bridge as shown in FIGS. 1 and 2a-2d above. Furthermore, the rectifier circuit in each embodiment of the electronic circuit described in the present disclosure may be implemented with the full-wave rectifier bridge is described as an example, which is not described below. It is to be noted that the rectifier circuit 200 is not limited to this kind of circuit structure.

In the embodiment, in order to achieve electrostatic protection of AC input/output, the present disclosure provides a first electrostatic protection circuit with the above circuit structure, and utilizes other components in the electronic circuit to fully utilize the unidirectional conduction characteristics of the diode. To form a discharge path so that the static electricity introduced from the AC input port or the output port of the electronic circuit is released through the discharge path. Accordingly, the static electricity will not enter the target circuit of the electronic circuit and thus the electronic components in the target circuit can be avoided to be damaged.

The electronic circuit further includes a Zener diode ZD1 and a current limiting resistor Rz coupled between the first output port Q1 and the second output port Q2 of the rectifier circuit 22 in series.

The Zener diode ZD1 can be set between two terminals of the rectifier circuit 200 to stabilize the voltage. However, since the Zener diode ZD1 is typically used for voltage clamping below several tens of volts, it can not be used to release the static voltage of the kilovolts, and the electrostatic current always passes through the Zener diode ZD1, which can weaken its life.

The current limiting resistor Rz is coupled with the Zener diode ZD1 with a large resistance. A voltage dividing of a branch with the Zener diode ZD1 and the current limiting resistor Rz is increased.

When the static electricity is introduced from the first AC input port P1 or the second AC input port P2 of the electronic circuit, the impedance of the branch composed of the Zener diode ZD1 and the current limiting resistor R1 is large, the static electricity is discharged by the dotted path as shown in FIGS. 2a-2d, so as to avoid the electrostatic current flowing through the Zener diode ZD1 branch of the static discharge, the Zener diode ZD1 can be protected.

In the embodiment, the first electrostatic protection circuit 110 is provided. When the external AC power is supplied to the electronic circuit, the first electrostatic protection circuit 110 and the diodes in the rectifier circuit 200 form a discharge path, a breakdown of the diodes of the rectifier circuit 200 and the Zener diode ZD1 can be avoided. Thus, internal components of the rectifier circuit 200 and the Zener diode ZD1 can be protected.

The discharge path for discharging static electricity in the embodiment is not limited to the dotted line shown in FIGS. 2a-2d, and can be determined according to the specific operation of the electronic circuit.

FIG. 3 shows an electronic circuit according to another embodiment. The electrostatic protection circuit can further include a second electrostatic protection circuit 120 coupled between the first AC input port P1 and the second AC input port P2, a third electrostatic protection circuit 130 coupled between the first input terminal A1 and the second output port Q2, and/or a fourth electrostatic protection circuit 140 coupled between the second input terminal A2 and the second output port Q2.

For the circuit configuration of the electrostatic protection circuit 100 including at least one of the second electrostatic protection circuit 120, the third electrostatic protection circuit 130, and the fourth electrostatic protection circuit 140, and the first electrostatic protection circuit 110, reference may be made to FIG. 3.

For the electronic circuit of the electrostatic protection circuit 100 provided with the second electrostatic protection circuit 120, when the external AC power source powers the electronic circuit, the second electrostatic protection circuit 120 may be directly connected to the first AC input terminal P1 of the external AC power source and the second AC input terminals P2 form a discharge path, such as the dotted line in FIG. 3, so that the static electricity introduced by the external AC power source is directly discharged, thereby avoiding the destruction of electronic components in the electronic circuit.

In describing the circuit configuration of each of the electrostatic protection circuits in the electrostatic protection circuit 100 in any one of the above embodiments, the drawings of the present disclosure only describe the circuit configuration of the first electrostatic protection circuit 110 based on the constitution of the static electricity protection circuit 100. For example, the circuit structures of the second electrostatic protection circuit 120, the third electrostatic protection circuit 130 and the fourth electrostatic protection circuit 140 in the above embodiments are similar, and are not described in detail herein.

In one embodiment, any one of the electrostatic protection circuit 100, the first electrostatic protection circuit 110, the second electrostatic protection circuit 120, and the third electrostatic protection circuit 130 in any one of the above embodiments is provided with an electrostatic protection circuit may comprise at least one semiconductor element.

It is to be noted that the present disclosure does not limit the type, number, and composition of the at least one semiconductor element. When the electronic circuit does not generate static electricity, the at least one semiconductor element is in a high resistance state so that an operating current of electronic circuit does not pass these electrostatic protection circuits, thus avoiding the impact of these electrostatic protection circuits on the normal operation of the electronic circuit. And when the electronic circuit has an electrostatic occurrence, that is, the electronic circuit described above introduces static electricity, then the at least one semiconductor element can operate in an avalanche breakdown state so as to form a discharge path in the manner described in the above embodiments, and the static electricity can be released.

Since the discharge path does not pass through the target circuit 300, the static electricity introduced into the electronic circuit does not enter the target circuit 300, thereby preventing the electronic components in the target circuit 300 from being electrostatically destroyed.

In another embodiment, the electrostatic protection circuit can include an electrostatic detection circuit and at least one semiconductor elements.

When the electronic circuit does not generate static electricity, the at least one semiconductor element controlled by the electrostatic detection circuit is in a high resistance state so that an operating current of electronic circuit does not pass these electrostatic protection circuits, thus avoiding the impact of these electrostatic protection circuits on the normal operation of the electronic circuit.

When the electronic circuit has an electrostatic occurrence, that is, when the electrostatic detection circuit detects a current or voltage of the static electricity, then the at least one semiconductor element can operate in a conduction state so as to form a discharge path in the manner described in the FIGS. 2a-2d and 3, and the static electricity can be released.

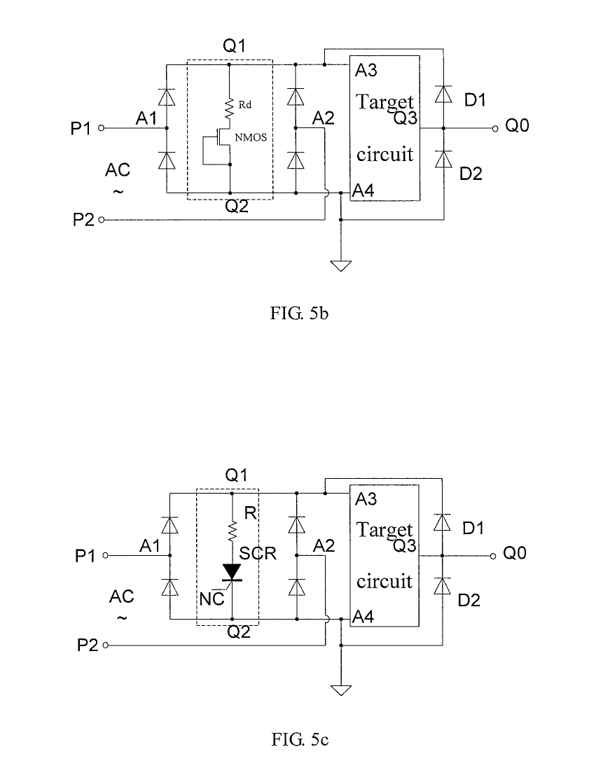

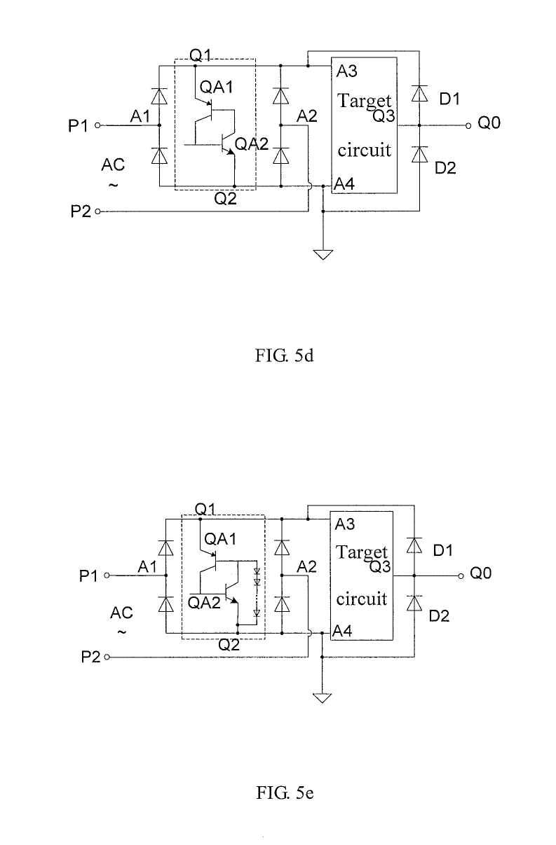

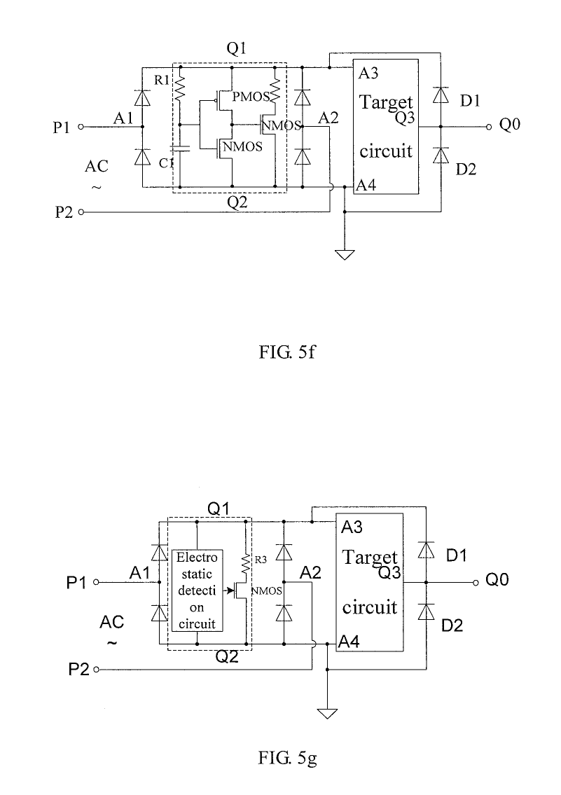

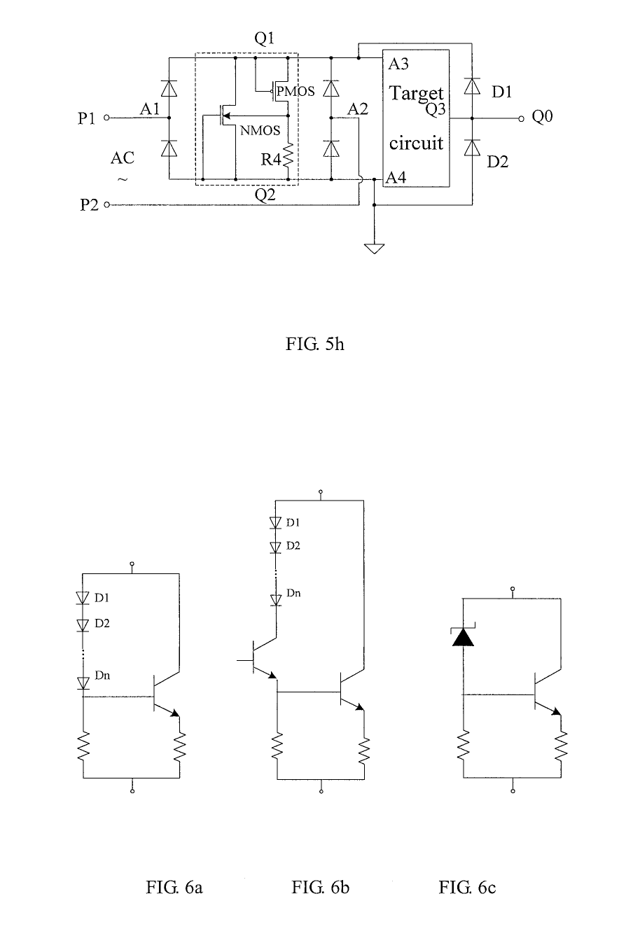

As shown in FIG. 5a, any one of the electrostatic protection circuit of the electrostatic protection circuit 100 can include a second Zener diode ZD2. A cathode of the second Zener diode ZD2 is coupled to the first output port Q1 of the rectifier circuit 200, an anode of the second Zener diode ZD2 is coupled to the second output port Q2.

When the electronic circuit does not generate static electricity, the second Zener diode ZD2 is in a high impedance state and will not affect the normal operation of the electronic circuit. When the electronic circuit has an electrostatic occurrence, the second Zener diode ZD2 enters a complete conducting state after an avalanche breakdown to form a discharge path to release static electricity.

As shown in FIG. 5b, any one of the electrostatic protection circuit 100 can include a first NMOS transistor. A drain of the first NMOS transistor is coupled to the first output terminal Q1 of the rectifier circuit 200. A gate of the first NMOS transistor is coupled to a source of the first NMOS transistor. The source of the first NMOS is coupled to the second output terminal Q2.

As shown in FIG. 5b, any one of the electrostatic protection circuit 100 can further include a resistor Rd coupled with the first NMOS transistor between the first output terminal Q1 and the second output terminal Q2.

When the electronic circuit does not generate static electricity, the first NMOS transistor is in an off state and will not affect the normal operation of the electronic circuit. When the electronic circuit has an electrostatic occurrence, the first NMOS transistor is conductive to form a discharge path to release static electricity.

As shown in FIG. 5c, the any one of the first, second, third, and the fourth electrostatic protection circuit can include a silicon controlled rectifier (SCR). An anode of the silicon controlled rectifier is coupled to the first output terminal Q1. A cathode of the silicon controlled rectifier is coupled to the second output terminal Q2. A control terminal of the silicon controlled rectifier receives an external control signal.

As shown in FIG. 5d, the silicon controlled rectifier can include a PNP transistor QA1 and an NPN transistor QA2. A base electrode of the PNP transistor QA1 is connected to a collector electrode of the NPN transistor QA2. A collector electrode of the PNP transistor QA1 is connected to a base electrode of the NPN transistor QA2. An emitter electrode of the PNP transistor QA1 is used as a port of the electrostatic protection circuit and connected to the first output terminal Q1 of the rectifier circuit 200. The emitter electrode of the NPN transistor QA2 can be connected to the second output terminal Q2 of the rectifier circuit 200 as the other port of the electrostatic protection circuit.

When the electronic circuit does not generate static electricity, the PNP transistor is in an off state and will not affect the normal operation of the electronic circuit. When the electronic circuit has an electrostatic occurrence, the first NMOS transistor is conductive to form a discharge path to release static electricity.

When the electronic circuit has static electricity (i.e. an electrostatic voltage is generated), a voltage difference between the emitter electrode and the base electrode of PNP transistor QA1 is 0.7V and a collector current is zero. Therefore, the PNP transistor QA1 is turned off so that the electrostatic voltage is mostly between the collector electrode and the emitter electrode of the NPN transistor QA2, and when the voltage between the collector electrode and the emitter electrode reaches an avalanche breakdown threshold, a leakage current can flow through the collector electrode and the emitter electrode of NPN transistor QA2, and the leakage current increases, a base current of PNP transistor QA1 will gradually increase, the PNP transistor QA1 is turned on.

Since the collector current of the PNP transistor QA1 is the base current of the NPN transistor QA2, the collector current of the PNP transistor QA1 increases as the leakage current increases when the PNP transistor QA1 is turned on, that is, the base current of NPN transistor QA2 will increase. The NPN transistor QA2 enters into a saturation state until it is fully conductive, the emitter and base electrodes of the PNP transistor QA1 and the collector and emitter electrodes of the NPN transistor QA2 has a low resistance path to form a discharge path to release the static electricity.

FIG. 5e shows an electrostatic protection circuit which is similar to the electrostatic protection circuit of FIG. 5d except that a plurality of diodes is coupled between the collector electrode and the emitter electrode of the NPN transistor.

When the PNP transistor QA1 is turned on, the plurality of diodes are configured to clamp voltage to turn of the NPN transistor QA1, thus a reverse breakdown can be avoided.

In another embodiment, the plurality of diodes can be replaced by other elements having a certain impedance to clamp voltage, and the connection manner of the other elements having a certain impedance in the electronic circuit is similar to that of the circuit shown in FIG. 5e.

In another embodiment, as shown in FIG. 5c, a resistor R may be provided between the first output terminal Q1 and the second output terminal Q2 of the rectifier circuit 200. In the unidirectional silicon controlled rectifier shown in FIG. 5d, the collector electrode of the PNP transistor QA1 can be connected to the emitter electrode of the NPN transistor QA2 via the resistor R.

As shown in FIG. 5f, any one of the first electrostatic protection circuit 110, the second electrostatic protection circuit 120, and the third electrostatic protection circuit 130, and even the fourth electrostatic protection circuit 140 and the fifth electrostatic 150 may include a first resistor R1, a first capacitor C1, a first PMOS transistor, a second NMOS transistor, a second resistor R2, and a third NMOS transistor.

One end of the first resistor R1 is connected to the first output terminal Q1 of the rectifier circuit 200, and the other end of the first resistor R1 is connected to one end of the first capacitor C1. The other end of the first capacitor C1 is connected to the second output end Q2 of the rectifier circuit 200.

A drain of the first PMOS transistor is connected to the first output terminal Q1 of the rectifier circuit 200. A gate of the first PMOS transistor is respectively connected to the other end of the first resistor R1 and a gate of the second NMOS transistor. A source is respectively connected to a drain of the second NMOS transistor and a gate of the third NMOS transistor. A source of the second NMOS transistor is connected to the second output terminal Q2 of the rectifier circuit 200, and a drain of the third NMOS transistor passes through the second the resistor R2 is connected to the first output terminal Q1 of the rectifier circuit 200. The source of the third NMOS transistor is connected to the second output terminal Q2 of the rectifier circuit 200.

In the embodiment, the first resistor R1, the first capacitor C1, the first PMOS transistor and the second NMOS transistor form the electrostatic detection circuit. When the electronic circuit has static electricity, the third NMOS transistor is conductive to form the discharge path to release the static electricity.

In another embodiment, as shown in FIG. 5g, any one of the first electrostatic protection circuit 110, the second electrostatic protection circuit 120, and the third electrostatic protection circuit 130, and the fourth electrostatic protection circuit 140 can include an electrostatic detection circuit 150, a third resistor R3, and a fourth NMOS transistor.

A first terminal of the electrostatic detection circuit 150 is connected to the first output terminal Q1 of the rectifier circuit 200. A second terminal of the electrostatic detection circuit 150 is connected to the second output terminal Q2 of the rectifier circuit 200. A third terminal is connected to a gate electrode of the fourth NMOS transistor. A source electrode of the NMOS transistor is connected to the second output terminal Q2 of the rectifier circuit 200, and a drain electrode thereof is connected to the first output terminal Q1 of the rectifier circuit 200 through the third resistor R3.

Based on the circuit structure, when the electrostatic detection circuit detects the introduction of static electricity into the electronic circuit, the fourth NMOS transistor will be turned on to form a discharge path to release the static electricity introduced by the electronic circuit and prevent the static electricity. When the electronic circuit does not generate static electricity, the fourth NMOS transistor will be in the off state.

In another embodiment, as shown in FIG. 5h, any one of the first electrostatic protection circuit 110, the second electrostatic protection circuit 120, and the third electrostatic protection circuit 130, and the fourth electrostatic protection circuit 140 can include a fourth resistor R4, a second PMOS transistor and a fifth NMOS transistor.

A gate electrode and a drain electrode of the second PMOS transistor are connected to the first output terminal Q1 of the rectifier circuit 200. A source electrode of the second PMOS transistor is connected to the second output terminal Q2 of the rectifier circuit 200 via the fourth resistor R4. A drain electrode of the fifth NMOS transistor is connected to the first output terminal Q1 of the rectifier circuit 200. A gate electrode and a source electrode of the fifth NMOS transistor are connected to the second output terminal Q2 of the rectifier circuit 200. A substrate of the fifth NMOS transistor is connected to the source of the second PMOS transistor.

In the embodiment, the second PMOS transistor and the fourth resistor R4 form the electrostatic detection circuit. When the electrostatic detection circuit detects the introduction of static electricity into the electronic circuit, the second PMOS transistor will enter an avalanche breakdown state, so that the fifth NMOS transistor is in the conducting state, thereby forming a discharge circuit Release the static electricity in the electronic circuit to avoid damaging the components in the target circuit.

The specific circuit structure of each of the electrostatic protection circuits in the electrostatic protection circuit 100 can be determined according to actual needs. Specifically, it can be selected from the above-mentioned FIGS. 5a-5h and 6a-6c.

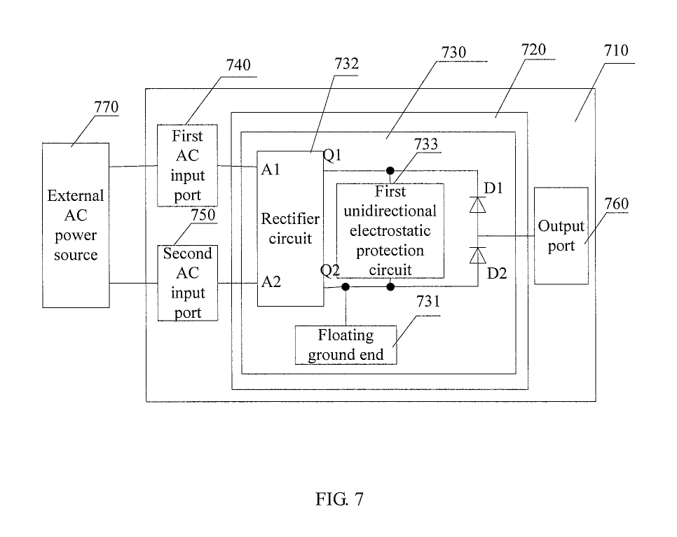

FIG. 7 shows a block diagram of an integrated circuit according to one embodiment. The integrated circuit can include a housing 710, a semiconductor substrate 720 arranged in the housing, an electronic circuit 730 arranged on the semiconductor 720. The integrated circuit can further include a first input port 740, a second input port 750, and an output port 760 which are extending from the housing 710.

The first input port 740 and the second input port 750 are coupled to an external AC power source 770.

The electronic circuit 730 can include a floating ground end 731, a rectifier circuit 732, a first unidirectional electrostatic protection circuit 733, a first diode D1, and a second diode D2.

The floating ground end 731 can be set inside or outside of the housing 710.

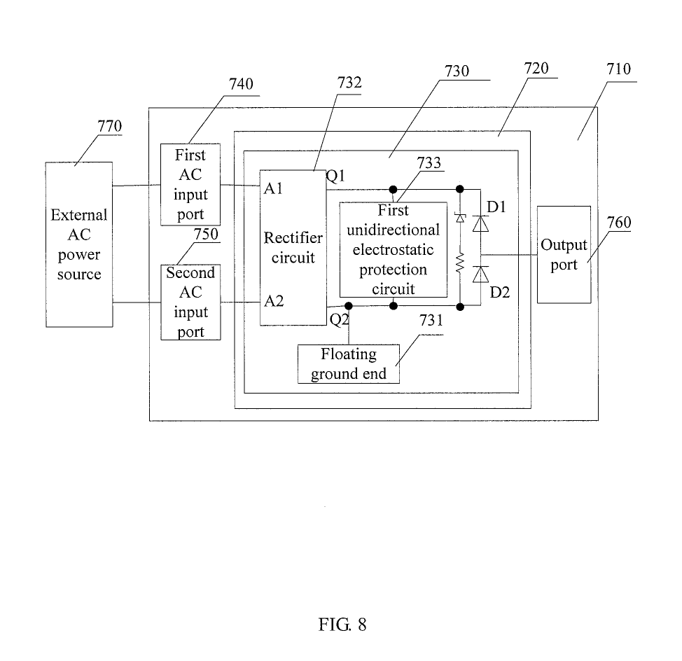

The rectifier circuit 732 can include two input terminals (A1 and A2 in FIG. 8) and two output terminals (Q1 and Q2 in FIG. 8). The two input terminals are respectively connected to the first AC input port 740 and the second AC input port 750, respectively. One terminal (Q2 in FIG. 8) having a lower voltage among the two output terminals is floated and can be connected to the floating port 731.

The first input terminal A1 of the rectifier circuit 732 is connected to the first AC input port 740. The second input terminal A2 of the rectifier circuit 732 is connected to the second AC input port 750. The first output terminal Q1 of the rectifier circuit 732 is connected to one end of the first unidirectional electrostatic protection circuit 733. The second output terminal Q2 of the rectifier circuit 732 is connected to the floating ground end 731.

The other end of the first unidirectional electrostatic protection circuit 733 is coupled to the floating ground end 731. A cathode of the first diode D1 is coupled to the first output terminal Q1 of the rectifier circuit 732. An anode of the first diode D1 is coupled to the output port 760. An anode of the second diode D2 is coupled to the floating ground end 731, and a cathode of the second diode D2 is coupled to the output port 760.

When static electricity is generated in the integrated circuit, a discharge path can be formed by first unidirectional electrostatic protection circuit 732, the first input port 740, the second input port 750 and the output port 760 to release static electricity. The electronic components of the electronic circuit can be avoided to damage by the static electricity.

In another embodiment, the floating ground end 731 can be omitted, the other end of the first unidirectional electrostatic protection circuit 733 is coupled to the second output terminal Q2.

As shown in FIG. 8, the electronic circuit 730 can further include a Zener diode and a current limiting resistor coupled between the two output terminals of the rectifier circuit 735 in series.

The first unidirectional electrostatic protection circuit 732 can be selected from the first electrostatic protection circuit 110, the second electrostatic protection circuit 120, and the third electrostatic protection circuit 130, and even the fourth electrostatic protection circuit 140 and the fifth electrostatic 150 as described-above.

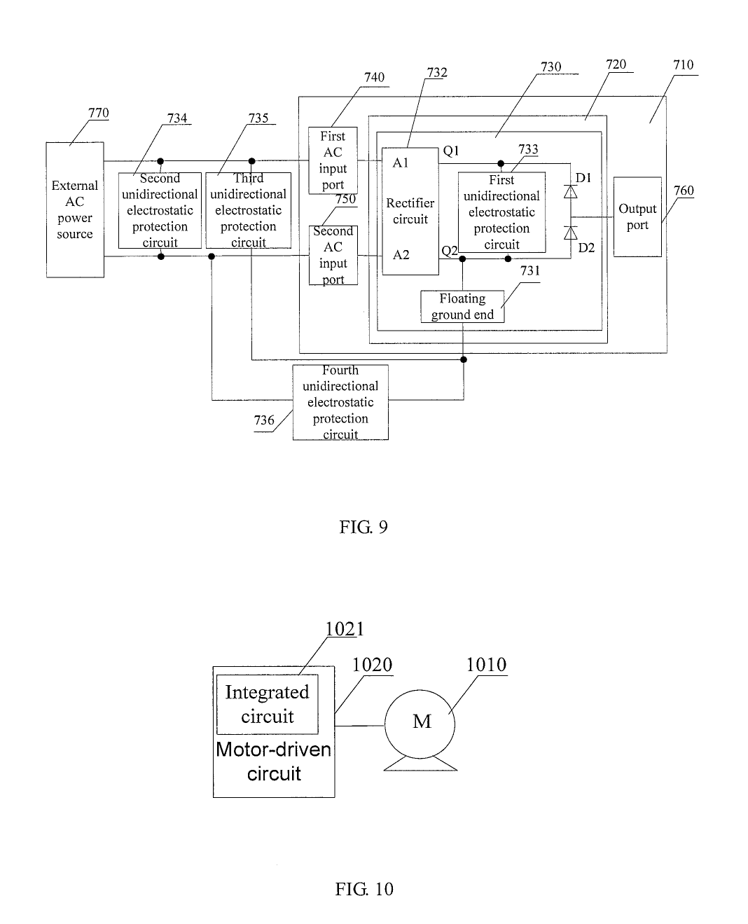

In another embodiment, as shown in FIG. 9, the electronic circuit 730 can further include a second unidirectional electrostatic circuit 734 coupled between the first AC input port 740 and the second AC input port 750, a third unidirectional electrostatic circuit 735 coupled between the first input terminal (the first AC input port 740) and the second output port Q2 (the floating ground end 731), and/or a fourth unidirectional electrostatic circuit 736 coupled between the second input terminal A2 (the second AC input port 750) and the second output terminal (the floating ground end 731).

The specific circuit structure of the second unidirectional electrostatic protection circuit 734, the third unidirectional electrostatic protection circuit 735, and the fourth unidirectional electrostatic protection circuit 736 may be the same as the circuit structure of the first unidirectional electrostatic protection circuit 733 described above, The unidirectional electrostatic protection circuit having the above structure is disposed in an electronic circuit of an integrated circuit, and at least one discharge path is generated by the unidirectional electrostatic protection circuit and other components when static electricity is generated in the integrated circuit to release the static electricity.

FIG. 10 shows a motor assembly according to one embodiment. The motor assembly can include a motor 1010 and a motor-driven circuit 1020. The motor-driven circuit 1020 can include an integrated circuit 1021. The integrated circuit 1021 is similar to the described-above integrated circuit, the present embodiment will not describe in detail.

Accordingly, an application apparatus is further provided according to an embodiment of the present disclosure. The application apparatus can include the motor assembly as described-above. Optionally, the application apparatus may be a pump, a fan, a household appliance, a vehicle and the like, where the household appliance, for example, may be a washing machine, a dishwasher, a range hood, an exhaust fan and the like

Described above are preferable embodiments of the present disclosure, which are not intended to limit the present disclosure. All the modifications, equivalent replacements and improvements in the scope of the spirit and principles of the present disclosure are in the protection scope of the present disclosure.

1. An electronic circuit, comprising:
an output port;
a first AC input port and a second AC input port connecting with an external AC power source;
a rectifier circuit having a first input terminal coupling with the first AC input port, a second input terminal coupling with the second AC input port, a first output terminal and a second output terminal, wherein a voltage of the first output terminal is larger than a voltage of the second output terminal; and
an electrostatic protection circuit having a first unidirectional electrostatic protection circuit coupled between the first output terminal of the rectifier circuit and the second output terminal of the rectifier circuit.

2. The electronic circuit of claim 1, wherein the second output terminal is a floating ground end.

3. The electronic circuit of claim 1, wherein an input terminal of the first unidirectional electrostatic circuit is electrically coupled with the first output terminal of the rectifier circuit; and an output terminal of the first unidirectional electrostatic circuit is electrically coupled with the second output terminal of the rectifier circuit.

4. The electronic circuit of claim 1, further comprising a Zener diode and a current limiting resistor coupled between the first output terminal of the rectifier circuit and the second output terminal of the rectifier circuit in series.

5. The electronic circuit of claim 1, wherein the electrostatic protection circuit comprises a second unidirectional electrostatic protection circuit coupled between the first AC input port and the second AC input port, a third unidirectional electrostatic protection circuit coupled between the first input terminal of the rectifier circuit and the second output terminal of the rectifier circuit, and/or a fourth unidirectional electrostatic protection circuit coupled between the second input terminal of the rectifier circuit and the second output terminal of the rectifier circuit.

6. The electronic circuit of claim 5, wherein at least one of the first, second, third, and fourth unidirectional electrostatic protection circuit comprises at least one semiconductor element; when an static electricity is not generated in the electronic circuit, the at least one semiconductor element is in a high resistance state, and when the static electricity is generated in the electronic circuit, the at least one semiconductor element operates in an avalanche breakdown state to form a discharge path to release the static electricity.

7. The electronic circuit of claim 5, wherein at least one of the first, second, third, and fourth unidirectional electrostatic protection circuit comprises an electrostatic detection circuit and a semiconductor element, and when an static electricity is not generated in the electronic circuit, the semiconductor element is in a high resistance state; and when the static electricity is generated in the electronic circuit, the semiconductor element is controlled to be conductive by the electrostatic detection circuit to form a discharge path to release the static electricity.

8. The electronic circuit of claim 5, wherein at least one of the first, second, third, and fourth unidirectional electrostatic protection circuit comprises a Zener diode, an anode of the Zener diode is electrically coupled between an input terminal and an output terminal of the unidirectional electrostatic protection circuit.

9. The electronic circuit of claim 5, wherein at least one of the first, second, third, and fourth unidirectional electrostatic protection circuit comprises a first NMOS transistor, a drain of the first NMOS transistor is electrically coupled to an input terminal of the unidirectional electrostatic protection circuit and a gate, and a source of the first NMOS transistor is electrically coupled to an output terminal of the unidirectional electrostatic protection circuit.

10. The electronic circuit of claim 5, wherein at least one of the first, second, third, and fourth unidirectional electrostatic protection circuit comprises a silicon controlled rectifier; an anode of the silicon controlled rectifier is electrically coupled to an input terminal of the unidirectional electrostatic protection circuit, a cathode of the silicon controlled rectifier is electrically coupled to an output terminal of the unidirectional electrostatic protection circuit, and a control terminal receives an external control signal.

11. The electronic circuit of claim 5, wherein at least one of the first, second, third, and fourth unidirectional electrostatic protection circuit comprises a PNP transistor and an NPN transistor; and a base electrode of the PNP transistor is electrically coupled with a collector electrode of the NPN transistor, a collector electrode of the PNP transistor is electrically coupled with a base electrode of the NPN transistor, an emitter electrode of the PNP transistor is electrically coupled with an input terminal of the unidirectional electrostatic protection circuit, and an emitter electrode of the NPN transistor is electrically coupled with an output terminal of the unidirectional electrostatic protection circuit.

12. The electronic circuit of claim 11, further comprising a plurality of diodes coupled between the collector electrode and the emitter electrode of the NPN transistor.

13. The electronic circuit of claim 5, wherein at least one of the first, second, third, and fourth unidirectional electrostatic protection circuit comprises a first resistor, a first capacitor, a first PMOS transistor, a second NMOS transistor, a second resistor, and a third NMOS transistor;
one end of the first resistor is electrically coupled with an input terminal of the unidirectional electrostatic protection circuit, the other end of the first resistor is electrically coupled with one end of the first capacitor;
the other end of the first capacitor coupled with an output terminal of the unidirectional electrostatic protection circuit;
a drain of the first PMOS transistor is coupled with an input terminal of the unidirectional electrostatic protection circuit, a gate of the first PMOS transistor is coupled with the other end of the first resistor and a gate of the second NMOS transistor, a source of the first PMOS transistor is coupled to a drain of the second NMOS transistor and a gate of the third NMOS transistor, a source of the second NMOS is coupled with an output terminal of the unidirectional electrostatic protection circuit;
a drain of the third NMOS transistor is coupled to the input terminal of the unidirectional electrostatic protection circuit via the second resistor, and a source of the third NMOS transistor is coupled to the output terminal of the unidirectional electrostatic protection circuit.

14. The electronic circuit of claim 5, wherein at least one of the first, second, third, and fourth unidirectional electrostatic protection circuit comprises an electrostatic detection circuit, a third resistor, and a fourth NMOS transistor;
a first end of the electrostatic detection circuit is coupled to an input terminal of the unidirectional electrostatic protection circuit, a second end of the electrostatic detection circuit is coupled to an output terminal of the unidirectional electrostatic protection circuit, and a third end of the electrostatic detection circuit is coupled to a gate of the fourth NMOS transistor;
a source of the fourth NMOS transistor is coupled with the output terminal of the unidirectional electrostatic detection circuit, and a drain of the fourth NMOS transistor is coupled with the input terminal of the unidirectional electrostatic detection circuit via the third resistor.

15. The electronic circuit of claim 5, wherein at least one of the first, second, third, and fourth unidirectional electrostatic protection circuit comprises a fourth resistor, a second PMOS, and a fifth NMOS transistor;
a gate and a drain of the second PMOS transistor are coupled with an input terminal of the unidirectional electrostatic detection circuit, a source of the second PMOS transistor is coupled to an output terminal of the unidirectional electrostatic detection circuit via the fourth resistor;
a drain of the fifth NMOS transistor is coupled with the input terminal of the unidirectional electrostatic detection circuit, a gate and a source of the fifth NMOS transistor are coupled with the output terminal of the unidirectional electrostatic detection circuit, and a substrate of the fifth NMOS transistor is coupled with the source of the second PMOS transistor.

16. An integrated circuit, comprising:
a housing;
a semiconductor substrate arranged in the housing;
an electronic circuit arranged on the substrate;
an output port; and
a first AC input port and a second AC input port connecting with an external AC power source; and
wherein the electronic circuit comprises a rectifier circuit coupled between the first AC input port and the second AC input port and a first unidirectional electrostatic protection circuit, and the first unidirectional electrostatic protection circuit is coupled between a first output terminal of the rectifier circuit and a second output terminal of the rectifier circuit.

17. The integrated circuit of claim 16, wherein an input terminal of the first unidirectional electrostatic circuit is electrically coupled with the first output terminal of the rectifier circuit; and an output terminal of the first unidirectional electrostatic circuit is electrically coupled with the second output terminal of the rectifier circuit.

18. The integrated circuit of claim 16, further comprising a second unidirectional electrostatic protection circuit coupled between the first AC input port and the second AC input port, a third unidirectional electrostatic protection circuit coupled between the first input terminal of the rectifier circuit and the second output terminal of the rectifier circuit, and/or a fourth unidirectional electrostatic protection circuit coupled between the second input terminal of the rectifier circuit and the second output terminal of the rectifier circuit.

19. The integrated circuit of claim 18, wherein at least one of the first, second, third, and fourth unidirectional electrostatic protection circuit comprises at least one semiconductor element; when an static electricity is not generated in the electronic circuit, the at least one semiconductor element is in a high resistance state, and when the static electricity is generated in the electronic circuit, the at least one semiconductor element operates in an avalanche breakdown state to form a discharge path to release the static electricity.

20. A motor assembly, comprising:
a motor and a motor-driven circuit, wherein the motor-driven circuit comprises the integrated circuit of claim 16.
